(19) United States
(12) Patent Application Publication
(10) Pub. No.: US 2004/0101632 A1
(43) Pub. Date: May 27, 2004

(54) Method for curing low dielectric constant film by electron beam

(75) Inventors: Wen H. Zhu, Sunnyvale, CA (US); Tzu-Fang Huang, San Jose, CA (US); Lihua Li, San Jose, CA (US); Li-Qun Xia, Santa Clara, CA (US); Ellie Y. Yieh, San Jose, CA (US)

Correspondence Address: PATENT COUNSEL, APPLIED MATERIALS, INC., Legal Affairs Department, P. O. BOX 450A, Santa Clara, CA, 95052, US

(73) Assignee: Applied Materials, Inc.

(21) Appl. No.: 10/302,375

(22) Filed: Nov. 22, 2002

(51) Int. Cl. C23C 16/00; B05D 3/00

(52) U.S. Cl. 427/551; 427/255.28; 427/569

(57) ABSTRACT

A method for depositing a low dielectric constant film on a substrate. The method includes depositing a low dielectric constant film comprising silicon, carbon, oxygen and hydrogen in a chemical vapor deposition chamber. The method further includes exposing the low dielectric constant film to an electron beam having an exposure dose less than about 400 μC/cm2 at conditions sufficient to increase the hardness of the low dielectric constant film.

### CROSS-REFERENCE TO RELATED APPLICATIONS

This application is related to U.S. Ser. No. 10/115,832 (AMAT/5869) by Li et al. and entitled “HARDNESS IMPROVEMENT OF SILICON CARBOXY FILMS”, which is incorporated herein by reference.

### BACKGROUND OF THE INVENTION

1. Field of the Invention

Embodiments of the present invention relate to the fabrication of integrated circuits. More particularly, embodiments of the present invention relate to a process for depositing dielectric layers on a substrate.

2. Description of the Related Art

Integrated circuit geometries have dramatically decreased in size since such devices were first introduced several decades ago. Since then, integrated circuits have generally followed the two year/half-size rule (often called Moore's Law), which means that the number of devices on a chip doubles every two years. Today's fabrication facilities are routinely producing devices having 0.13 μm and even 0.1 μm feature sizes, and tomorrow's facilities soon will be producing devices having even smaller feature sizes.

The continued reduction in device geometries has generated a demand for films having lower k values because the capacitive coupling between adjacent metal lines must be reduced to further reduce the size of devices on integrated circuits. In particular, insulators having low dielectric constants (k), less than about 4.0, are desirable. Examples of insulators having low dielectric constants include spin-on glass, un-doped silicon glass (USG), fluorine-doped silicon glass (FSG), and polytetrafluoroethylene (PTFE), which are all commercially available.

An effective method to reduce the k value is to introduce pores into the film. As a result, low k films often have a low mechanical strength (e.g., hardness), which may hinder the integration of the films into the manufacture of the device. Plasma post treatment is currently being used to increase the mechanical strength of low k films. However, the plasma treatment causes the k value to increase.

A need, therefore, exists for a method to increase the mechanical strength of low k films without increasing the k value.

### SUMMARY OF THE INVENTION

Embodiments of the present invention are generally directed to a method for depositing a low dielectric constant film on a substrate. The method includes depositing a low dielectric constant film comprising silicon, carbon, oxygen and hydrogen in a chemical vapor deposition chamber. The method further includes exposing the low dielectric constant film to an electron beam having an exposure dose less than about 400 μC/cm² at conditions sufficient to increase the hardness of the low dielectric constant film.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional diagram of an exemplary CVD reactor configured for use according to embodiments described herein.

FIG. 2 is an electron beam chamber in accordance with an embodiment of the invention.

FIG. 3 is a fragmentary view of the electron beam chamber in accordance with an embodiment of the invention.

FIG. 4 illustrates the electron beam chamber with a feedback control circuit in accordance with an embodiment of the invention.

### DETAILED DESCRIPTION OF THE PREFERRED EMBODIMENT

A detailed description will now be provided. Various terms as used herein are defined below. To the extent a term used in a claim is not defined below, it should be given the broadest definition persons in the pertinent art have given that term, as reflected in printed publications and issued patents. Embodiments of the invention provide a significant and unexpected improvement in hardness, cracking threshold and electrical properties (e.g., leakage current and break down voltage) of an ultra low dielectric constant film. In one embodiment, a film containing silicon, carbon, oxygen, and hydrogen is deposited on a surface of a substrate at conditions sufficient to form an ultra low dielectric constant film (k less than 2.5). The ultra low dielectric constant film is then subjected to a post treatment of electron beam.

The ultra low dielectric constant film is generally formed by blending or mixing one or more precursor gases, which may include cyclic organosilicon compounds, aliphatic compounds, hydrocarbon compounds, and oxidizing compounds. The cyclic organosilicon compounds may include a ring structure having three or more silicon atoms and the ring structure may further comprise one or more oxygen atoms. Commercially available cyclic organosilicon compounds include rings having alternating silicon and oxygen atoms with one or two alkyl groups bonded to the silicon atoms. For example, the cyclic organosilicon compounds may include one or more of the following compounds:

| | |
|---|---|
| 1,3,5-trisilano-2,4,6-trimethylene, | (—SiH₂—CH₂—)₃— (cyclic) |
| 1,3,5,7-tetramethylcyclotetrasiloxane (TMCTS), | (—SiH(CH₃)—O—)₄— (cyclic) |
| octamethylcyclotetrasiloxane (OMCTS), | (—Si(CH₃)₂—O—)₄— (cyclic) |
| 1,3,5,7,9-pentamethylcyclopentasiloxane, | (—SiH(CH₃)—O—)₅— (cyclic) |
| 1,3,5,7-tetrasilano-2,6-dioxy-4,8-dimethylene, | (—SiH₂—CH₂—SiH₂—O—)₂— (cyclic) |
| hexamethylcyclotrisiloxane | (—Si(CH₃)₂—O—)₃— (cyclic) |

The aliphatic compounds include linear or branched (i.e. acyclic) organosilicon compounds having one or more silicon atoms, one or more carbon atoms, and linear or branched hydrocarbon compounds having at least one unsaturated carbon bond. The structures may further comprise oxygen. Commercially available aliphatic organosilicon compounds include organosilanes that do not contain oxygen between silicon atoms and organosiloxanes that contain oxygen between two or more silicon atoms. For example, the aliphatic organosilicon compounds may include one or more of the following compounds:

| | |
|---|---|
| methylsilane | CH₃—SiH₃ |
| dimethylsilane | (CH3)₂—SiH₂ |
| trimethylsilane | (CH3)₃—SiH |
| dimethyldimethoxysilane | (CH3)₂—Si—(O—CH₃)₂ |
| ethylsilane | CH₃—CH₂—SiH₃ |
| disilanomethane | SiH₃—CH₂—SiH₃ |
| bis(methylsilano)methane | CH₃—SiH₂—CH₂—SiH₂—CH₃ |
| 1,2-disilanoethane | SiH₃—CH₂—CH₂—SiH₃ |
| 1,2-bis(methylsilano)ethane | CH₃—SiH₂—CH₂—CH₂—SiH₂—CH₃ |
| 2,2-disilanopropane | SiH₃—C(CH₃) ₂—SiH₃ |
| 1,3-dimethyldisiloxane | CH₃—SiH₂—O—SiH₂—CH, |
| 1,1,3,3-tetramethyldisiloxane (TMDSO) | (CH₃)₂—SiH—O—SiH—(CH₃)₂ |
| hexamethyldisiloxane (HMDS) | (CH₃)₃—Si—O—Si—(CH₃)₃ |
| 1,3-bis(silanomethylene)disiloxane | (SiH₃—CH₂—SiH₂—)₂—O |
| bis(1-methyldisiloxanyl)methane | (CH₃—SiH₂—O—SiH₂—)₂—CH₂ |
| 2,2-bis(1-methyldisiloxanyl)propane | (CH₃—SiH₂—O—SiH₂—)₂—C(CH₃) ₂ |
| hexamethoxydisiloxane (HMDOS) | (CH₃—O)₃—Si—O—Si—(O—CH₃)₃ |
| diethylsilane | (C₂H₅)₂SiH₂ |
| propylsilane | C₃H₇SiH₃ |
| vinylmethylsilane | CH₂═CH—SiH₂—CH₃ |
| 1,1,2,2-tetramethyldisilane | (CH₃)—S:G—S:H—(CH₃)₂ |
| hexamethyldisilane | (CH₃)₃—Si—Si—(CH₃)₃ |
| 1,1,2,2,3,3-hexamethyltrisilane | (CH₃)₂—SiH—Si(CH₃)₂—SiH—(CH₃)₂ |
| 1,1,2,3,3-pentamethyltrisilane | (CH₃)₂SiH—SiH(CH₃)—SiH(CH₃)₂ |
| dimethyldisilanoethane | CH₃—SiH₂—(CH₂)₂—SiH₂—CH₃ |
| dimethyldisilanopropane | CH₃—SiH—(CH₂)₃—SiH—CH₃ |
| tetramethyldisilanoethane | (CH₃)₂—SiH—(CH₂)₂—SiH—(CH₃)₂ |
| tetramethyldisilanopropane | (CH₃)₂—SiH—(CH₂)₃—Si—(CH₃)₂ |

The hydrocarbon compounds have between one and about 20 adjacent carbon atoms. The hydrocarbon compounds may include adjacent carbon atoms that are bonded by any combination of single, double, and triple bonds. For example, the organic compounds may include alkenes and alkylenes having two to about 20 carbon atoms, such as ethylene, propylene, acetylene, and butadiene.

The one or more oxidizing gases may include oxygen (O₂), ozone (O₃), nitrous oxide (N₂O), carbon monoxide (CO), carbon dioxide (CO₂), water (H₂O), peroxide (H₂O₂) or combinations thereof. In one embodiment, the oxidizing gas is oxygen gas. In another embodiment, the oxidizing gas is ozone. When ozone is used as an oxidizing gas, an ozone generator converts from 6% to 20%, typically about 15%, by weight of the oxygen in a source gas to ozone, with the remainder typically being oxygen. However, the ozone concentration may be increased or decreased based upon the amount of ozone desired and the type of ozone-generating equipment used. The one or more oxidizing gases are added to the reactive gas mixture to increase reactivity and achieve the desired carbon content in the deposited film.

The deposited film contains a carbon content between about 5 and about 30 atomic percent (excluding hydrogen atoms), preferably between about 5 and about 20 atomic percent. The carbon content of the deposited films refers to atomic analysis of the film structure that typically does not contain significant amounts of non-bonded hydrocarbons. The carbon contents are represented by the percent of carbon atoms in the deposited film, excluding hydrogen atoms that are difficult to quantify. For example, a film having an average of one silicon atom, one oxygen atom, one carbon atom, and two hydrogen atoms has a carbon content of about 20 atomic percent (one carbon atom per five total atoms), or a carbon content of about 33 atomic percent, excluding hydrogen atoms (one carbon atom per three total atoms, other than hydrogen atoms).

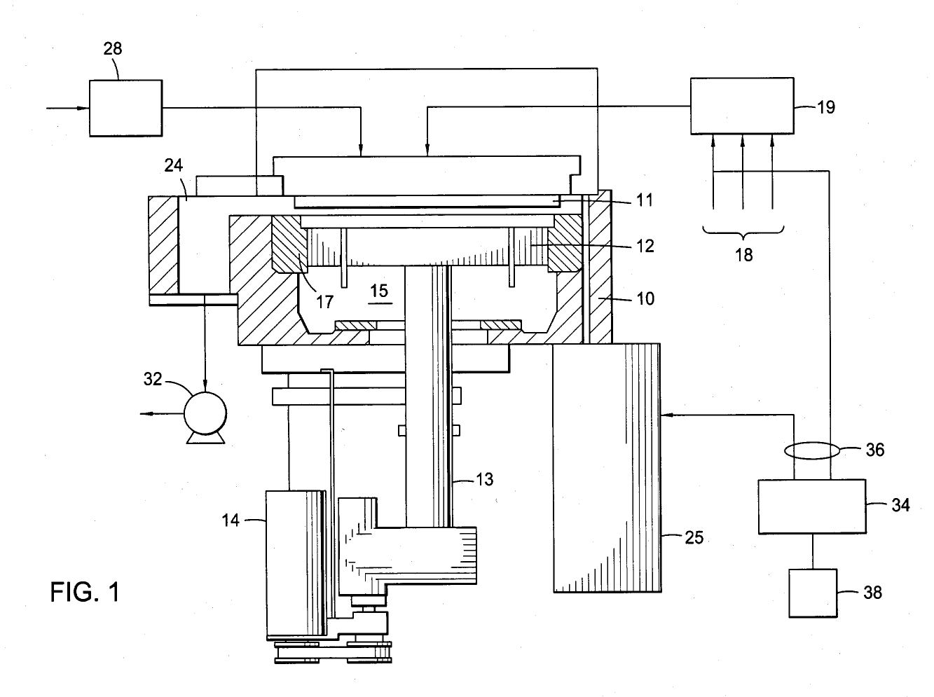

The film may be deposited using any processing chamber capable of chemical vapor deposition (CVD). Referring now FIG. 1, a vertical, cross-section view of a parallel plate CVD processing chamber 10 is illustrated. The chamber 10 includes a high vacuum region 15 and a gas distribution manifold 11 having perforated holes for dispersing process gases therethrough to a substrate (not shown). The substrate rests on a substrate support plate or susceptor 12. The susceptor 12 is mounted on a support stem 13 that connects the susceptor 12 to a lift motor 14. The lift motor 14 raises and lowers the susceptor 12 between a processing position and a lower, substrate-loading position so that the susceptor 12 (and the substrate supported on the upper surface of susceptor 12) can be controllably moved between a lower loading/off-loading position and an upper processing position which is closely adjacent to the manifold 11. An insulator 17 surrounds the susceptor 12 and the substrate when in an upper processing position.

Gases introduced to the manifold 11 are uniformly distributed radially across the surface of the substrate. A vacuum pump 32 having a throttle valve controls the exhaust rate of gases from the chamber 10 through a manifold 24. Deposition and carrier gases, if needed, flow through gas lines 18 into a mixing system 19 and then to the manifold 11. Generally, each process gas supply line 18 includes (i) safety shut-off valves (not shown) that can be used to automatically or manually shut off the flow of process gas into the chamber, and (ii) mass flow controllers (also not shown) to measure the flow of gas through the gas supply lines 18. When toxic gases are used in the process, several safety shut-off valves are positioned on each gas supply line 18 in conventional configurations.

During deposition, a blend/mixture of one or more cyclic organosilicon compounds and one or more aliphatic compounds are reacted with an oxidizing gas to form an ultra low k film on the substrate. The cyclic organosilicon compounds may be combined with at least one aliphatic organosilicon compound and at least one aliphatic hydrocarbon compound. For example, the mixture contains about 5 percent by volume to about 80 percent by volume of the one or more cyclic organosilicon compounds, about 5 percent by volume to about 15 percent by volume of the one or more aliphatic organosilicon compounds, and about 5 percent by volume to about 45 percent by volume of the one or more aliphatic hydrocarbon compounds. The mixture also contains about 5 percent by volume to about 20 percent by volume of the one or more oxidizing gases. Alternatively, the mixture may contain about 45 percent by volume to about 60 percent by volume of one or more cyclic organosilicon compounds, about 5 percent by volume to about 10 percent by volume of one or more aliphatic organosilicon compounds, and about 5 percent by volume to about 35 percent by volume of one or more aliphatic hydrocarbon compounds.

The one or more cyclic organosilicon compounds are typically introduced to the mixing system 19 at a flow rate of about 100 to about 10,000 sccm, preferably about 520 sccm. The one or more aliphatic organosilicon compounds are introduced to the mixing system 19 at a flow rate of about 100 to about 1,000 sccm, preferably about 600 sccm. The one or more aliphatic hydrocarbon compounds are introduced to the mixing system 19 at a flow rate of about 100 to about 10,000 sccm, preferably about 2,000 sccm. The oxygen containing gas has a flow rate between about 100 and about 6,000 sccm, preferably about 1,000 sccm. Preferably, the cyclic organosilicon compound is 1,3,5,7-tetramethylcyclotetrasiloxane, octamethylcyclotetrasiloxane, or a mixture thereof, and the aliphatic organosilicon compound is trimethylsilane, 1,1,3,3-tetramethyldisiloxane, or a mixture thereof. The aliphatic hydrocarbon compound is preferably ethylene.

The deposition process can be either a thermal process or a plasma-enhanced process. In a plasma enhanced process, a controlled plasma is typically formed adjacent the substrate by applying RF power to the gas distribution manifold 11 using an RF power supply 25. Alternatively, RF power can be provided to the susceptor 12. The RF power to the deposition chamber may be cycled or pulsed to reduce heating of the substrate and promote greater porosity in the deposited film. The power density of the plasma for a 300 mm substrate is between about 0.014 W/cm² and about 2.8 W/cm², which corresponds to an RF power level of about 10 W to about 2000 W. Preferably, the RF power level is between about 300 W and about 1700 W.

The RF power supply 25 can supply a single frequency RF power between about 0.01 MHz and 300 MHz. Alternatively, the RF power may be delivered using mixed, simultaneous frequencies to enhance the decomposition of reactive species introduced into the high vacuum region 15. In one embodiment, the mixed frequency is a lower frequency of about 12 kHz and a higher frequency of about 13.56 MHz. In another embodiment, the lower frequency may range between about 400 kHz and about 14 MHz, and the higher frequency may range between about 20 MHz and about 100 MHz.

During deposition, the substrate is maintained at a temperature between about −20° C. and about 500° C., preferably between about 100° C. and about 400° C. The deposition pressure is typically between about 0.5 Torr and about 20 Torr, preferably between about 2 Torr and about 8 Torr. The deposition rate is typically between about 5,000 A/min and about 20,000 A/min.

When remote dissociation of the oxidizing gas is desired, an optional microwave chamber 28 can be used to input power from between about 50 Watts and about 6,000 Watts to the oxidizing gas prior to the gas entering the processing chamber 10. The additional microwave power can avoid excessive dissociation of the organosilicon compounds prior to reaction with the oxidizing gas. A gas distribution plate (not shown) having separate passages for the organosilicon compound and the oxidizing gas is preferred when microwave power is added to the oxidizing gas.

Typically, any or the entire chamber lining, distribution manifold 11, susceptor 12, and various other reactor hardware are made out of materials such as aluminum or anodized aluminum. An example of such a CVD reactor is described in U.S. Pat. No. 5,000,113, entitled “A Thermal CVD/PECVD Reactor and Use for Thermal Chemical Vapor Deposition of Silicon Dioxide and In-situ Multi-step Planarized Process,” issued to Wang et al., and assigned to Applied Materials, Inc., the assignee of the invention, and is incorporated by reference herein to the extent not inconsistent with the invention.

A system controller 34 controls the motor 14, the gas mixing system 19, and the high frequency power supply 25, which are connected therewith by control lines 36. The system controller 34 controls the activities of the CVD reactor and typically includes a hard disk drive, a floppy disk drive, and a card rack. The card rack contains a single board computer (SBC), analog and digital input/output boards, interface boards, and stepper motor controller boards. The system controller 34 conforms to the Versa Modular Europeans (VME) standard, which defines board, card cage, and connector dimensions and types. The VME standard also defines the bus structure having a 16-bit data bus and a 24-bit address bus.

The pretreatment and method for forming a pretreated layer of the present invention is not limited to any specific apparatus or to any specific plasma excitation method. The above CVD system description is mainly for illustrative purposes, and other CVD equipment such as electrode cyclotron resonance (ECR) plasma CVD devices, induction-coupled RF high density plasma CVD devices, or the like may be employed. Additionally, variations of the above described system such as variations in substrate support pedestal design, heater design, location of power connections and others are possible. For example, the substrate could be supported and heated by a resistively heated substrate support pedestal.

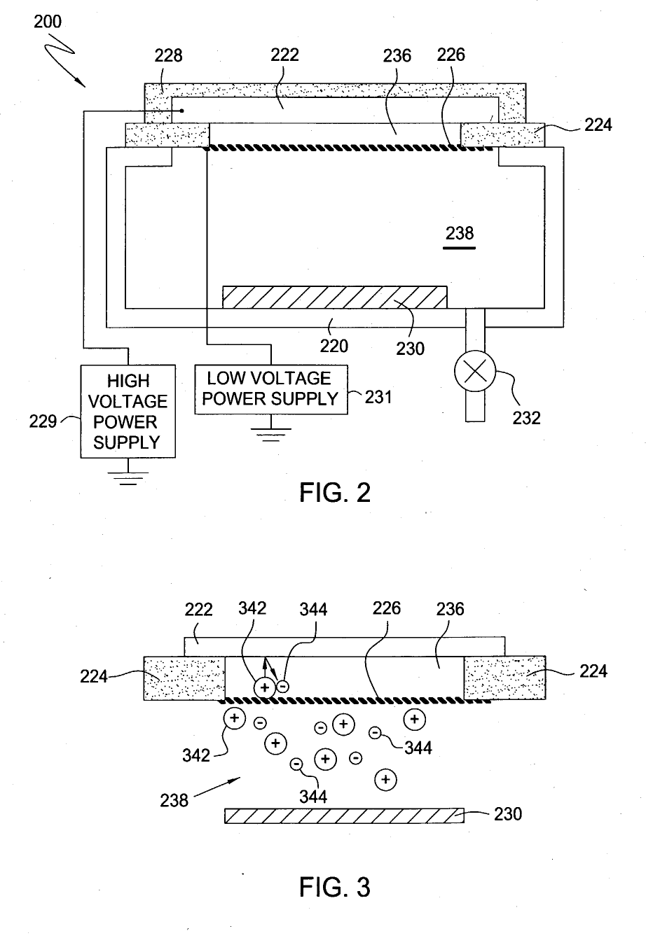

Once the film is deposited, the substrate is transferred to an electron beam (e-beam) apparatus for further processing, i.e., curing. The substrate may be transferred with vacuum break or under vacuum, i.e., without any vacuum break. FIG. 2 illustrates an e-beam chamber 200 in accordance with an embodiment of the invention. The e-beam chamber 200 includes a vacuum chamber 220, a large-area cathode 222, a target plane 230 located in a field-free region 238, and a grid anode 226 positioned between the target plane 230 and the large-area cathode 222. The e-beam chamber 200 further includes a high voltage insulator 224, which isolates the grid anode 226 from the large-area cathode 222, a cathode cover insulator 228 located outside the vacuum chamber 220, a variable leak valve 232 for controlling the pressure inside the vacuum chamber 220, a variable high voltage power supply 229 connected to the large-area cathode 222, and a variable low voltage power supply 231 connected to the grid anode 226.

In operation, the substrate (not shown) to be exposed with the electron beam is placed on the target plane 230. The vacuum chamber 220 is pumped from atmospheric pressure to a pressure in the range of about 1 mTorr to about 200 mTorr. The exact pressure is controlled by the variable rate leak valve 232, which is capable of controlling pressure to about 0.1 mTorr. The electron beam is generally generated at a sufficiently high voltage, which is applied to the large-area cathode 222 by the high voltage power supply 229. The voltage may range from about −500 volts to about 30,000 volts or higher. The high voltage power supply 229 may be a Bertan Model #105-30R manufactured by Bertan of Hickville, N.Y., or a Spellman Model #SL30N-1200×258 manufactured by Spellman High Voltage Electronics Corp., of Hauppauge, N.Y. The variable low voltage power supply 231 applies a voltage to the grid anode 226 that is positive relative to the voltage applied to the large-area cathode 222. This voltage is used to control electron emission from the large-area cathode 222. The variable low voltage power supply 231 may be an Acopian Model #150PT12 power supply available from Acopian of Easton, Pa.

To initiate electron emission, the gas in the field-free region 238 between the grid anode 226 and the target plane 30 must become ionized, which may occur as a result of naturally occurring gamma rays. Electron emission may also be artificially initiated inside the vacuum chamber 220 by a high voltage spark gap. Once this initial ionization takes place, positive ions 342 (shown in FIG. 3) are attracted to the grid anode 226 by a slightly negative voltage, i.e., on the order of about 0 to about −200 volts, applied to the grid anode 226. These positive ions 342 pass into the accelerating field region 236, disposed between the large-area cathode 222 and the grid anode 226, and are accelerated towards the large-area cathode 222 as a result of the high voltage applied to the large-area cathode 222. Upon striking the large-area cathode 222, these high-energy ions produce secondary electrons 344, which are accelerated back toward the grid anode 226. Some of these electrons 344, which travel generally perpendicular to the cathode surface, strike the grid anode 226, but many of these electrons 344 pass through the grid anode 226 and travel to the target plane 230. The grid anode 226 is preferably positioned at a distance less than the mean free path of the electrons emitted by the large-area cathode 222, e.g., the grid anode 226 is preferably positioned less than about 4 mm from the large-area cathode 222. Due to the short distance between the grid anode 226 and the large-area cathode 222, no, or minimal if any, ionization takes place in the accelerating field region 236 between the grid anode 226 and the large-area cathode 222.

In a conventional gas discharge device, the electrons would create further positive ions in the accelerating field region, which would be attracted to the large-area cathode 222, creating even more electron emission. The discharge could easily avalanche into an unstable high voltage breakdown. However, in accordance with an embodiment of the invention, the ions 342 created outside the grid anode 226 may be controlled (repelled or attracted) by the voltage applied to the grid anode 226. In other words, the electron emission may be continuously controlled by varying the voltage on the grid anode 226. Alternatively, the electron emission may be controlled by the variable leak valve 232, which is configured to raise or lower the number of molecules in the ionization region between the target plane 230 and the large-area cathode 222. The electron emission may be entirely turned off by applying a positive voltage to the grid anode 226, i.e., when the grid anode voltage exceeds the energy of any of the positive ion species created in the space between the grid anode 226 and target plane 230.

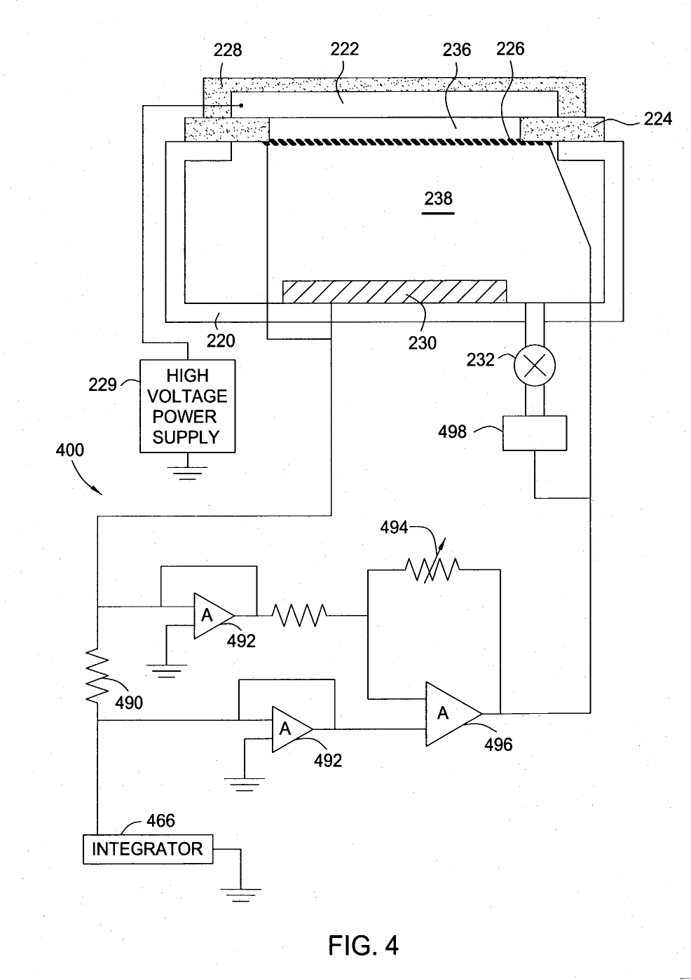

FIG. 4 illustrates the e-beam chamber 200 with a feedback control circuit 400. In some applications it may be desirable to provide a constant beam current at different electron beam energies. For example, it may be desirable to expose or cure the upper layer of the film formed on the substrate, but not the bottom layer. This may be accomplished by lowering the electron beam energy such that most of the electrons are absorbed in the upper layer of the film. Subsequent to curing the top layer, it may be desirable to cure the full thickness of the film. This can be done by raising the accelerating voltage of electron beam to penetrate completely through the film. The feedback control circuit 400 is configured to maintain a constant beam current independent of changes in the accelerating voltage. The feedback control circuit 400 includes an integrator 466. The beam current is sampled via a sense resistor 490, which is placed between the target plane 230 and the integrator 466. The beam current may also be sampled at the grid anode 226 as a portion of the beam is intercepted there. Two unity gain voltage followers 492 buffer the signal obtained across the sense resistor 490 and feed it to an amplifier 496 with a variable resistor 494. The output of this amplifier controls the voltage on the grid anode 226 such that an increase in beam current will cause a decrease in bias voltage on the grid anode 226 and a decrease in beam current from the large-area cathode 222. The gain of the amplifier 496 is adjusted, by means of the variable resistor 494, so that any change in beam current caused by a change in the accelerating voltage is counteracted by a change in bias voltage, thereby maintaining a constant beam current at the target. Alternatively, the output of the amplifier 496 may be connected to a voltage controlled variable rate leak valve 298 to counteract changes in beam current by raising or lowering the pressure in the ionization region 238. Further, a wider range of beam current control may be provided by utilizing feedback signals to both the variable leak valve 298 and the grid anode 226. Other details of the e-beam chamber 200 are described in U.S. Pat. No. 5,000,178, entitled “Large-Area Uniform Electron Source”, issued to William R. Livesay, assigned to Electron Vision Corporation (which is currently owned by the assignee of the present invention) and is incorporated by reference herein to the extent not inconsistent with the invention.

The temperature at which the e-beam chamber 200 operates ranges from about −200 degrees Celsius to about 600 degrees Celsius, e.g., about 200 degrees Celsius to about 400 degrees Celsius. The electron beam energy ranges from about 0.5 KeV to about 30 KeV. The exposure dose ranges from about 1 μC/cm² to about 400 μC/cm², and more preferably between about 50 to about 200 μC/cm², such as about 70 μC/cm². The electron beams are generally generated at a pressure of about 1 mTorr to about 100 mTorr. The gas ambient in the electron beam chamber 220 may be any of the following gases: nitrogen, oxygen, hydrogen, argon, a blend of hydrogen and nitrogen, ammonia, xenon, or any combination of these gases. The electron beam current ranges from about 1 mA to about 40 mA, and more preferably from about 5 mA to about 20 mA. The electron beam may cover an area from about 4 square inches to about 700 square inches.

An Example:

The following example illustrates a low dielectric film with an improved hardness. The film was deposited using a plasma-enhanced chemical vapor deposition chamber. In particular, the film was deposited using a “Producer” system, available from Applied Materials, Inc. of Santa Clara, Calif.

The low dielectric constant film was deposited on a 300 mm substrate from the following reactive gases at a chamber pressure of about 5.75 Torr and a substrate temperature of about 400° C.

Octamethylcyclotetrasiloxane (OMCTS), at about 520 sccm;

Trimethylsilane (TMS), at about 600 sccm;

Ethylene, at about 2,000 sccm;

Oxygen, at about 1,000 sccm; and

Helium, at about 1,000 sccm.

The substrate was positioned 1,050 mils from the gas distribution showerhead. A power level of about 800 W at a frequency of 13.56 MHz was applied to the gas distribution manifold for plasma-enhanced deposition of the film. The film was deposited at a rate of about 12,000 A/min, and had a dielectric constant (k) of about 2.54 measured at 0.1 MHz.

The film was then treated using an electron beam apparatus, such as the e-beam chamber 200 described above, at the conditions described below for about 90 seconds. During the post treatment, the chamber temperature was about 400 degrees Celsius, the electron beam energy was about 4 KeV, and the electron beam current was about 3 mA. The exposure dose of the electron beam was about 70 μC/cm². Argon was flowed into the chamber at a rate of about 150 sccm for the entire curing process. After the post treatment, the dielectric constant of the film remained about the same, i.e., about 2.54. The hardness of the film increased from about 0.66 GPa to about 1.40 GPa, while the modulus of the film increased from about 4.2 GPa to about 8.3 GPa. The thickness cracking threshold of the film increased from about 8000 Å to about 24,000 Å. The leakage current of the film decreased by at least an order of magnitude, e.g., from about 3.46×10⁻¹⁰ A/cm² to about 5.72×10⁻¹¹ A/cm² (at about 1 MV/cm). The break down voltage of the film increased from about 4.2 MV to about 4.7 MV.

While the foregoing is directed to embodiments of the present invention, other and further embodiments of the invention may be devised without departing from the basic scope thereof, and the scope thereof is determined by the claims that follow.

What is claimed is:

1. A method for depositing a low dielectric constant film on a substrate, comprising:
depositing a low dielectric constant film comprising silicon, carbon, oxygen and hydrogen in a chemical vapor deposition chamber; and
exposing the low dielectric constant film to an electron beam having an exposure dose less than about 400 μC/cm² at conditions sufficient to increase the hardness of the low dielectric constant film.

2. The method of claim 1, wherein the chemical vapor deposition chamber is a plasma-enhanced chemical vapor deposition chamber.

3. The method of claim 2, wherein the depositing comprises:
introducing a gas mixture into the plasma-enhanced chemical vapor deposition chamber, the gas mixture comprising one or more compounds selected from a group consisting of cyclic organosilison compounds, aliphatic organosilicon compounds, hydrocarbon compounds, and oxidizing gases; and
reacting the gas mixture to form the low dielectric constant film on the substrate.

4. The method of claim 3, further comprising forming a plasma of the gas mixture inside the plasma-enhanced chemical vapor deposition chamber.

5. The method of claim 3, further comprising forming a plasma of the gas mixture using a radio frequency power having a frequency in a range from about 20 MHz to about 100 MHz.

6. The method of claim 1, wherein the conditions comprise an electron beam current ranging from about 1 mA to about 15 mA.

7. The method of claim 1, wherein the exposure dose of the electron beam is between about 50 μC/cm² to about 200 μC/cm².

8. The method of claim 1, wherein the exposure dose of the electron beam is about 70 μC/cm².

9. The method of claim 1, further comprising flowing argon gas at a rate of about 150 sccm across the low dielectric constant film.

10. The method of claim 1, wherein the low dielectric constant film has a dielectric constant of less than about 2.6.

11. The method of claim 1, wherein the conditions comprise a substrate temperature ranging from about −200 degrees Celsius to about 600 degrees Celsius.

12. The method of claim 1, wherein the conditions comprise an electron beam energy ranging from about 0.5 KeV to about 30 KeV.

13. The method of claim 3, wherein the cyclic organosilicon compounds comprise at least one silicon-carbon bond and at least one silicon-hydrogen bond.

14. The method of claim 3, wherein the hydrocarbon compounds comprise an unsaturated carbon-carbon bond.

15. The method of claim 1, wherein exposing the low dielectric constant film to the electron beam reduces the leakage current of the low dielectric constant film by at least about one order of magnitude.

16. The method of claim 3, wherein the cyclic organosilicon compounds are selected from the group consisting of 3,5-trisilano-2,4,6-trimethylene, 1,3,5,7-tetramethylcyclotetrasiloxane (TMCTS), octamethylcyclotetrasiloxane (OMCTS), 1,3,5,7,9-pentamethylcyclopentasiloxane, 1,3,5,7-tetrasilano-2,6-dioxy-4,8-dimethylene, and hexamethylcyclotrisiloxane.

17. The method of claim 3, wherein the aliphatic organosilicon compounds are selected from the group consisting of methylsilane, dimethylsilane, trimethylsilane, dimethyldimethoxysilane, ethylsilane, disilanomethane, bis(methylsilano)methane, 1,2-disilanoethane, 1,2-bis(methylsilano)ethane, 2,2-disilanopropane, 1,3-dimethyldisiloxane, 1,1,3,3-tetramethyldisiloxane (TMDSO), hexamethyldisiloxane (HMDS), 1,3-bis(silanomethylene)disiloxane, bis(1-methyldisiloxanyl)methane, 2,2-bis(1-methyldisiloxanyl)propane, diethylsilane, propylsilane, vinylmethylsilane, 1,1,2,2-tetramethyldisilane, hexamethyldisilane, 1,1,2,2,3,3-hexamethyltrisilane, 1,1,2,3,3-pentamethyltrisilane, dimethyldisilanoethane, dimethyldisilanopropane, tetramethyldisilanoethane, and tetramethyldisilanopropane.

18. The method of claim 3, wherein the hydrocarbon compounds are selected from the group consisting of ethylene, propylene, acetylene, butadiene, t-butylethylene, 1,1,3,3-tetramethylbutylbenzene, t-butylether, metyl-methacrylate (MMA), and t-butylfurfurylether.

19. The method of claim 3, wherein the cyclic organosilicon compounds are 1,3,5-trisilano-2,4,6-trimethylene, 1,3,5,7-tetramethylcyclotetrasiloxane (TMCTS), octamethylcyclotetrasiloxane (OMCTS), or a mixture thereof.

20. The method of claim 3, wherein the aliphatic oranosilicon compounds comprise methylsilane, dimethylsilane, trimethylsilane, or a mixture thereof.

21. The method of claim 3, wherein the hydrocarbon compounds comprise ethylene.
